(19) United States
(12) Patent Application Publication
(10) Pub. No.: US 2017/0077455 A1
(43) Pub. Date: Mar. 16, 2017

(54) FILM PACKAGING DEVICE

(71) Applicant: SUZHOU INSTITUTE OF NANO-TECH AND NANO-BIONICS OF CHINESE ACADEMY OF SCIENCE, Suzhou (CN)

(72) Inventors: Wenming Su, Suzhou (CN); Zheng Cui, Suzhou (CN); Fei Fei, Suzhou (CN); Dongyu Zhang, Suzhou (CN); Minshun Song, Suzhou (CN)

(21) Appl. No.: 15/123,469

(22) PCT Filed: Mar. 11, 2015
(86) PCT No.: PCT/CN2015/074026

§ 371 Date: Sep. 2, 2016

(30) Foreign Application Priority Data
Mar. 13, 2014 (CN) 201410093342.2

(51) Int. Cl. H01L 51/52; H01L 51/10; H01L 51/00; H01L 51/44

(52) U.S. Cl. CPC H01L 51/5259; H01L 51/5253; H01L 51/448; H01L 51/107; H01L 51/0097; H01L 2251/5338

(57) ABSTRACT

The disclosure provides a film packaging device, which introduces a drying layer having no influence on the transmittance and stability of a substrate into a packaging structure of a film barrier layer. The drying layer is in a filled groove structure, has a strong hygroscopic effect and has no influence on light transmission at the same time, and can avoid the damage and influence on the stability of the barrier layer and a functional layer of the device caused by hygroscopic expansion. The introduced drying layer may increase the water and oxygen permeation resistance effect of the barrier layer by 1 or 2 orders of magnitude, thereby having an important action on the improvement of the service life of a flexible device, and the drying layer may also be used in an organic/inorganic multilayer alternating flexible packaging film structure, thereby reducing the number of organic/inorganic alternating layers on the basis of guaranteeing a water and oxygen barrier effect.

### TECHNICAL FIELD

The disclosure relates to the field of packaging technologies, and specifically to a film packaging device.

### BACKGROUND

Most devices such as display, diode and micro electro-mechanical sensor all need to be protected by completely sealed physical packages. Studies have shown that water vapor, oxygen and the like elements in air have a great influence on the service life of OLED, and the reason mainly comes from the following aspects: since electrons need to be injected from the cathode when the OLED device is working, a lower cathode work function is better; however, common cathode materials such as metallic aluminum and magnesium-calcium generally are active and are easy to react with penetrated water vapor and oxygen. In addition, water vapor also reacts chemically with a hole transport layer and an electron transport layer, or causes an interface contact problem; as all these reactions will cause a failure of the device, effectively packaging the OLED and separating each functional layer of the device from the water vapor, oxygen and the like elements in air may greatly prolong the service life of the device. For example, for organic photoelectric devices such as OLED, organic photovoltaic devices, OTFT and so on, since these organic photoelectric devices are sensitive to the water vapor and oxygen in air which will directly influence the service life, the efficiency and other performances of the devices, in order to prevent the rapid aging and instability of the organic photoelectric devices, generally these devices need to be packaged.

To improve the performance of OLED devices and prolong the service life thereof, besides selecting an optimal function material and optimizing device structures, besides improving the surface smoothness of a substrate material to prevent the damage on a luminescent layer of the device caused by an uneven surface, and preventing the peel-off of an organic functional layer from an ITO film, it is more important to prevent water vapor and oxygen from penetrating into the device through a substrate, a packaging cover plate and a packaging adhesive interface to cause a failure of the devices. When the method to improve the performance and stability of OLED devices by selecting an optimal function material and optimizing device structures and by improving the surface of the substrate material runs into the development bottleneck, a good method is to start with the packaging material and packaging technology. Therefore, to improve the service life of devices, it is very important to develop a packaging material and technology which has a good barrier property for water vapor and oxygen.

At present, the common packaging technology is a glass or metal cover plate packaging technology with a glass substrate, a single-layer or multi-layer inorganic film packaging technology, and an organic and inorganic alternating Barix film packaging technology.

For the first packaging technology, please refer to FIG. 1, a substrate layer 40, an ITO layer 30, an OLED 50 and a packaging isolation layer 10 are disposed in turn from the bottom up, wherein the packaging isolation layer 10 and the ITO layer 30 are bonded via a UV processed epoxy resin 20. This structure disposes between the packaging isolation layer 10 and the OLED 50 a desiccant 60 which absorbs water vapor and oxygen and prevents penetrated water vapor and oxygen from acting on the OLED device and thus improves the service life of the device. This structure is the main packaging method applied to the industry of photoelectric devices with a glass substrate, only applicable to nonflexible and non-film packaging devices.

For the second packaging technology, please refer to FIG. 2, a flexible substrate 40, an ITO layer 30 and an OLED 10 are disposed in turn from bottom up, and an inorganic barrier layer film 20 is employed to enclose the device, to realize an all-round protection; however, this structure is rigid, which is difficult to achieve the technical index of 1×10−6 g/m2/d.

The third one is a flexible packaging method, which is the most common packaging method for realizing flexible display. An organic-inorganic overlapped structure is employed to protect a device; this overlapped film packaging structure has flexibility and is a common method for present flexible film packaging technologies. However, to achieve the technical index of 1×10−6 g/m2/d, there is a very high demand on the smoothness of an organic layer, on the density of an inorganic layer, on the quality of non-defective pinholes and so on, and 3 to 5 or more times of overlaps are needed to achieve a corresponding effect.

### SUMMARY

The technical problem to be solved by the disclosure is to provide a film packaging device, which solves the problem that film packaging cannot use a desiccant and further solves the problem that the structure stability of a barrier layer and a functional layer of the device is impacted after the desiccant is expanded.

In order to solve the above technical problem, the disclosure provides a film packaging device, including:

a substrate;

a functional layer; and

a drying layer, at least one surface of which is opened with a grid-type groove in which a desiccant is filled.

Preferably, at least one surface of the substrate is opened with a grid-type groove in which a desiccant is filled to form the drying layer.

Preferably, the film packaging device further includes a barrier layer which comprises a first barrier layer and a second barrier layer located on the upper and lower sides of the functional layer respectively, wherein the substrate, the functional layer and the second barrier layer are formed on the first barrier layer in turn.

Preferably, the film packaging device further includes a barrier layer which comprises a first barrier layer and a second barrier layer located on the upper and lower sides of the functional layer respectively.

Preferably, at least one surface of at least one barrier layer is opened with a grid-type groove in which a desiccant is filled to form the drying layer.

Preferably, the drying layer is located between the first barrier layer and the second barrier layer.

Preferably, the groove has a width of 2 to 15 um and a depth of 2 to 20 um.

Preferably, the substrate is glass, a stainless sheet or a flexible substrate; the material of the flexible substrate is selected from one or more of PET, PEN, PI, PC and PMMA.

Preferably, the desiccant is a water-absorption active material; the desiccant is an active metal, a metallic oxide, P₂O₅ or a water-absorption salt, with a particle size of 1 to 200 nm.

Preferably, the barrier layer is a dense inorganic film or an organic-inorganic overlapped film.

The disclosure provides a film packaging device, which in particular introduces a drying layer having no influence on the transmittance and stability of a substrate into a packaging structure of a film barrier layer. The drying layer is in a filled groove structure, has a strong hygroscopic effect and has no influence on light transmission at the same time, and can avoid the damage and influence on the stability of the barrier layer and a functional layer of the device caused by hygroscopic expansion. The introduced drying layer may increase the water and oxygen permeation resistance effect of the barrier layer by 1 or 2 orders of magnitude, thereby having an important action on the improvement of the service life of a flexible device, and the drying layer may also be used in an organic/inorganic multilayer alternating flexible packaging film structure, thereby reducing the number of organic/inorganic alternating layers on the basis of guaranteeing a water and oxygen barrier effect.

### BRIEF DESCRIPTION OF THE DRAWINGS

FIG. 1 is a diagram of a first structure in the existing technologies.

FIG. 2 is a diagram of a second structure in the existing technologies.

FIG. 3 is a structure diagram of a film packaging device according to an Embodiment 1 of the disclosure.

FIG. 4 is a structure diagram of a drying layer according to an Embodiment 1 of the disclosure.

FIG. 5 is a structure diagram of a groove-type grid of the drying layer in FIG. 4.

FIG. 6 is another structure diagram of a film packaging device according to an Embodiment 1 of the disclosure.

FIG. 7 is a structure diagram of a film packaging device according to an Embodiment 2 of the disclosure.

FIG. 8 is a structure diagram of a film packaging device according to an Embodiment 3 of the disclosure.

FIG. 9 is a structure diagram of a film packaging device according to an Embodiment 4 of the disclosure.

FIG. 10 is a structure diagram of a combination of a drying layer and a functional layer according to an Embodiment 4 of the disclosure.

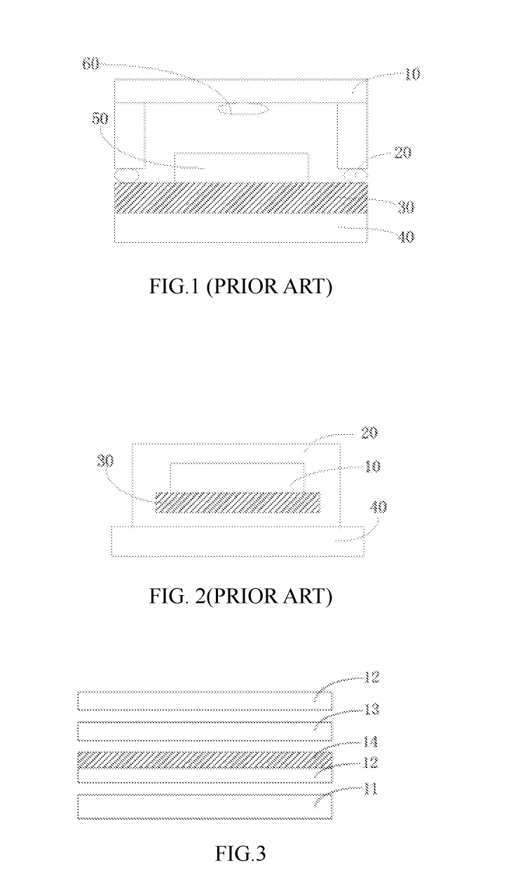

### DESCRIPTION OF THE EMBODIMENTS

The disclosure provides a film packaging device, which includes a substrate, a functional layer and a drying layer. At least one surface of the drying layer is opened with a grid-type groove in which a desiccant is filled. The drying layer is designed for the purpose of preventing penetrated water vapor and oxygen damaging the device, absorbing water vapor, deoxygenating and prolonging the service life of the device.

Further, the film packaging device further includes a barrier layer, which is configured for protecting the functional layer; the drying layer may be disposed in the barrier layer or disposed independently.

The disclosure is described below in further detail in conjunction with accompanying drawings and specific embodiments.

### Embodiment 1

Please refer to FIG. 3, the film packaging device includes a substrate 11, a barrier layer 12, a functional layer 13 and a drying layer 14, wherein the functional layer 13 includes a first surface and a second surface opposite the first surface, the barrier layer 12 is disposed on the first surface and the second surface of the functional layer 13, at least one part or the entirety of at least one barrier layer 12 is a drying layer 14, the drying layer 14 includes a substrate 141 and a groove-type grid 142, wherein the groove-type grid 142 is disposed on the surface of the substrate 141 and a desiccant is filled in the groove-type grid 142. The substrate 141 may be a structure similar to the barrier layer 12 or may be a structure supporting the groove-type grid 142.

In this embodiment, the functional layer 13 is sandwiched between two barrier layers 12 so as to be protected from the upper and lower directions. In particular, the functional layer 13 may be a device such as OLED structure, display, photovoltaic device, diode and micro electro-mechanical sensor. In this embodiment, the barrier layer 12 is a glass, metal or dense pinhole-free inorganic film, adopting a structure with a very small clearance between molecules to prevent the entrance of general water vapor molecules and oxygen molecules, thereby guaranteeing that the service life of the device may be prolonged. In this embodiment, the substrate 11 may be a flexible material such as glass, stainless sheet, PET, PEN, PI, PC and PMMA.

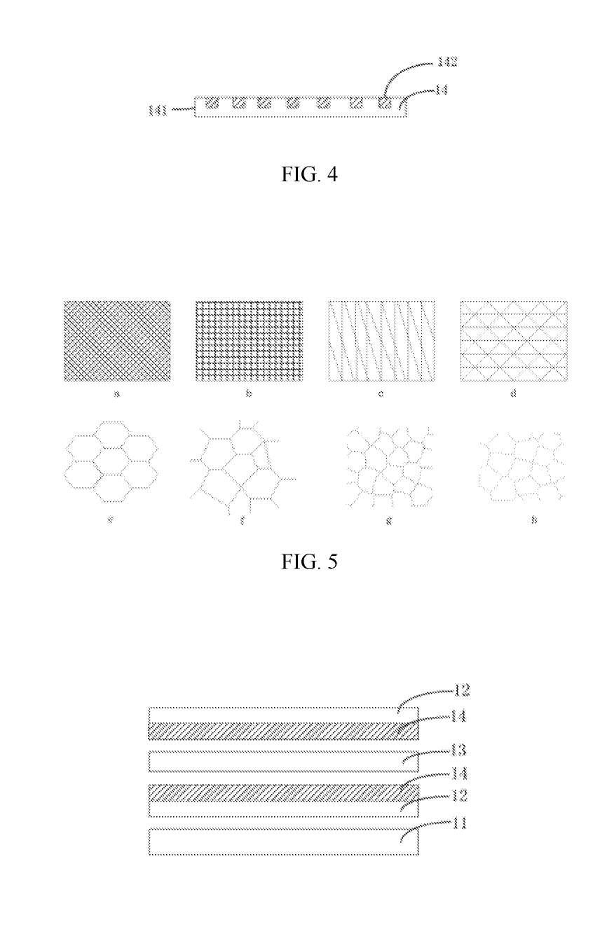

Please refer to FIG. 4, which is a sectional view of the drying layer 14, the drying layer 14 has a groove-type grid 142 disposed on the surface of the substrate 141; as shown in FIG. 5, the groove-type grid 142 may be in different shapes shown therein, for example, a square having certain angle relative to the horizontal direction shown in FIG. 5a, or a square structure shown in FIG. 5b, or a parallelogram structure shown in FIG. 5c, or a triangle structure shown in FIG. 5d, or a regular hexagon shown in FIG. 5e, or an irregular grid shown in FIG. 5f, FIG. 5g and FIG. 5h. The groove-type grid 142 is filled with a desiccant which is selected from a water-absorption active material and which may be an active metal, a metallic oxide, P₂O₅ or a water-absorption salt with a particle size of 1 to 200 nm. The structure of the drying layer 14 shown in FIG. 4 may well absorb water vapor and oxygen; moreover, as the desiccant will not fall off or expand to influence or damage the structure of the barrier layer 12 and the functional layer when the desiccant is embedded into and limited by the groove-type grid 142, the normal operation of the device can be guaranteed and the light transmission of the device will not be influenced. The groove-type grid 142 has a width of 2 to 15 um and a depth of 2 to 20 um; preferably, the groove-type grid 142 has a width of 3 to 10 um and a depth of 2 to 10 um.

Please refer to FIG. 6 which is a preferable film packaging structure of this embodiment, both sides of the functional layer are provided with a drying layer; this structure can better absorb water vapor and oxygen entered therein using the desiccant from the upper and lower sides of the functional layer, thereby preventing the function device being damaged by the water vapor and oxygen.

### Embodiment 2

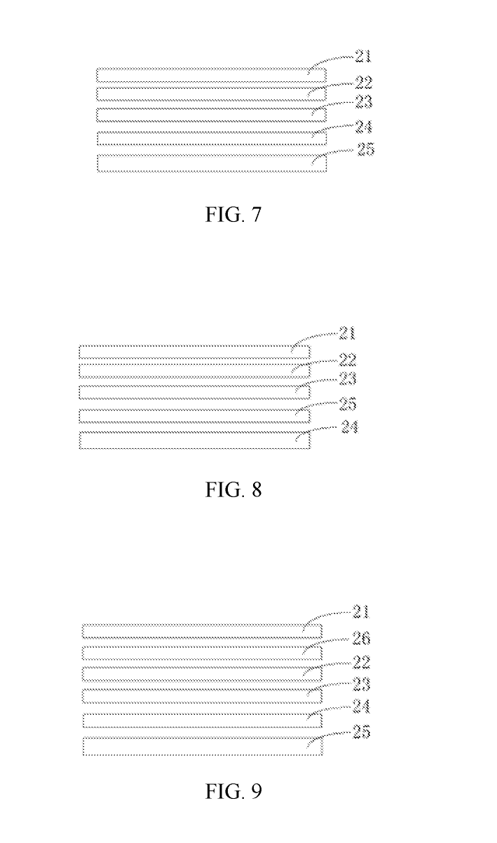

Please refer to FIG. 7, which is another preferred embodiment, the film packaging device includes a second barrier layer 21, a functional layer 22, a first drying layer 23, a first barrier layer 24 and a substrate 25 in turn from top down. This structure can better prevent the penetration of water vapor and oxygen, achieving a double-layer protection; likewise, a barrier layer may be added to the surrounding of the device, to effectively prevent the penetration of water vapor and oxygen at the edge. The structure of the first drying layer 23 also is a groove-type grid (not marked here) in which a desiccant is filled; the groove-type grid adds a constraint to the desiccant, well preventing the falloff of the desiccant while well achieving the function of drying, and not influencing the light transmission.

This embodiment is taken as an example to illustrate a preparation method thereof below.

Depositing a first barrier layer (50 nm SiO2/500 nm silicon polymer) using ICP-PECVD on a flexible substrate PEN, then, coating a liquid UV cured imprint adhesive, laminating and pressing using an imprint template and then curing under 365 nm ultraviolet rays to form a transparent plastic layer. Peeling off the imprint template and forming a hexagonal grid-type groove on the transparent plastic layer, wherein the groove has a depth of 4.5 um and a width of 2.8 um.

Filling a desiccant pulp in the groove, scraping the desiccant on the surface layer using a scraper and baking for 2 hours at 130 degrees C. in vacuum, to complete the preparation of the desiccant layer. Depositing an electrode, a device functional layer and a second barrier layer above the desiccant layer in turn to finish the film packaging device described in this embodiment.

### Embodiment 3

Please refer to FIG. 7 and FIG. 8 which is another film device packaging structure, the substrate 25 and the first barrier layer 24 are exchanged in position on the basis of Embodiment 2. This structure may also well protect the device. In this embodiment, it also may be that the flexible substrate contains a barrier layer.

### Embodiment 4

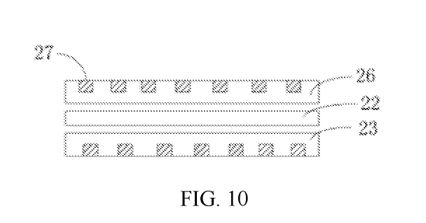

Please refer to FIG. 7 and FIG. 9 which is another preferred embodiment, this structure adds a second drying layer 26 on the basis of Embodiment 2, that is, there are two drying layers 26, 23, which are disposed on two sides of the functional layer 22 respectively; meanwhile, refer to FIG. 10, the drying layers 26, 23 are laminated such that the groove-type grid 27 side is far away from the surface of the functional layer 22, in this way the problem of falloff of desiccant does not need to be considered at all and the service life of the device gets an absolute guarantee. Also, this structure may dispose a barrier layer at the edge of the device, to form an all-round protection for the device. In addition, the first drying layer 23 may also be disposed between the substrate 25 and the first barrier layer 24, achieving the same protection.

The disclosure provides a film packaging device, which in particular introduces a drying layer having no influence on the transmittance and stability of a substrate into a packaging structure of a film barrier layer. The drying layer is in a filled groove structure, has a strong hygroscopic effect and has no influence on light transmission at the same time, and can avoid the damage and influence on the stability of the barrier layer and a functional layer of the device caused by hygroscopic expansion. The introduced drying layer may increase the water and oxygen permeation resistance effect of the barrier layer by 1 or 2 orders of magnitude, thereby having an important action on the improvement of the service life of a flexible device, and the drying layer may also be used in an organic/inorganic multilayer alternating flexible packaging film structure, thereby reducing the number of organic/inorganic alternating layers on the basis of guaranteeing a water and oxygen barrier effect and reducing the packaging cost

It should be understood that, for those of ordinary skill in the art, other changes and variations may be made according to the technical idea of the disclosure, and all these changes and variations are intended to be included in the protection scope of the claims appended below.

1. A film packaging device, comprising:
a substrate and a functional layer; and
a drying layer, at least one surface of which is opened with a grid-type groove in which a desiccant is filled.

2. The film packaging device according to claim 1, wherein at least one surface of the substrate is opened with a grid-type groove in which a desiccant is filled to form the drying layer.

3. The film packaging device according to claim 2, further comprising a barrier layer which comprises a first barrier layer and a second barrier layer located on the upper and lower sides of the functional layer respectively, wherein the substrate, the functional layer and the second barrier layer are formed on the first barrier layer in turn.

4. The film packaging device according to claim 1, further comprising a barrier layer which comprises a first barrier layer and a second barrier layer located on the upper and lower sides of the functional layer respectively.

5. The film packaging device according to claim 4, wherein at least one surface of at least one barrier layer is opened with a grid-type groove in which a desiccant is filled to form the drying layer.

6. The film packaging device according to claim 4, wherein the drying layer is located between the first barrier layer and the second barrier layer.

7. The film packaging device according to claim 1, wherein the groove has a width of 2 to 15 um and a depth of 2 to 20 um.

8. The film packaging device according to claim 1, wherein the substrate is selected from at least one of glass, stainless sheet and flexible substrate.

9. The film packaging device according to 8, wherein the material of the flexible substrate is selected from at least one of PET, PEN, PI, PC and PMMA.

10. The film packaging device according to claim 1, wherein the desiccant is a water-absorption active material and is selected from at least one of active metal, metallic oxide, P₂O₅ or water-absorption salt.

11. The film packaging device according to 10, wherein the desiccant has a particle size of 1 to 200 nm.

12. The film packaging device according to claim 1, wherein the barrier layer is a dense inorganic film or an organic-inorganic overlapped film.
